(19) United States
(12) Patent Application Publication
(10) Pub. No.: US 2010/0133700 A1
(43) Pub. Date: Jun. 3, 2010

(54) PERFORMANCE ENHANCEMENT IN METALLIZATION SYSTEMS OF MICROSTRUCTURE DEVICES BY INCORPORATING GRAIN SIZE INCREASING METAL FEATURES

(76) Inventors: Thomas Werner, Moritzburg (DE); Oliver Aubel, Dresden (DE); Frank Feustel, Dresden (DE)

Correspondence Address: WILLIAMS, MORGAN & AMERSON, 10333 RICHMOND, SUITE 1100, HOUSTON, TX, 77042, US

(21) Appl. No.: 12/624,517

(22) Filed: Nov. 24, 2009

(30) Foreign Application Priority Data
Nov. 28, 2008 (DE) 10 2008 059 503.9

(51) Int. Cl. H01L 23/522; H01L 21/768

(52) U.S. Cl. 257/774; 438/627; 438/637; 257/E23.145; 257/E21.584; 257/E21.577

(57) ABSTRACT

In a sophisticated metallization system, enhanced electromigration behavior may be accomplished by incorporating electromigration barriers into metal lines after a given distance, which may be accomplished by providing an increased width in order to obtain an enhanced average grain size in the intermediate metal regions of increased lateral width. Consequently, the electromigration induced material diffusion may encounter an overall increased grain size along the entire depth of the metal lines, thereby resulting in a significantly reduced electromigration effect and thus enhanced reliability of the critical metal lines.

### BACKGROUND OF THE INVENTION

1. Field of the Invention

Generally, the present disclosure relates to microstructures, such as advanced integrated circuits, and, more particularly, to metallization systems, such as metal lines in metallization layers of integrated circuits.

2. Description of the Related Art

In the field of modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption. As the size of individual circuit elements is reduced with every new circuit generation, thereby improving, for example, the switching speed of the transistor elements, the available floor space for interconnect lines electrically connecting the individual circuit elements is also decreased. Consequently, the dimensions of these interconnect lines have to be reduced to compensate for a reduced amount of available floor space and for an increased number of circuit elements provided per unit die area. The reduced cross-sectional area of the interconnect lines, possibly in combination with an increase of the static power consumption of extremely scaled transistor elements, may require a plurality of stacked metallization layers to meet the requirements in view of a tolerable current density in the metal lines.

Advanced integrated circuits, including transistor elements having a critical dimension of approximately 100 nm and less, may, however, require significantly increased current densities in the individual metal lines, despite the provision of a relatively large number of metallization layers, owing to the high number of circuit elements per unit area. Operating the metal lines at elevated current densities, however, may entail a plurality of problems related to stress-induced line degradation, which may finally lead to a premature failure of the integrated circuit. One prominent phenomenon in this respect is the current-induced material diffusion in metal lines, also referred to as “electromigration,” which may lead to the formation of voids within and hillocks next to the metal line, thereby resulting in reduced performance and reliability or complete failure of the device. Electromigration is a phenomenon that typically occurs in metal lines when a significant momentum transfer from electrons to the core atoms or ions takes place. Due to this momentum transfer, the atoms or ions are displaced and thus move in the direction of the electron flow, thereby increasingly depleting upstream areas of less pronounced electromigration resistance, while accumulating metal material in specific downstream areas. This material depletion may increasingly reduce the cross-sectional area of the upstream area and may finally result in a total failure of the metal line. The directed diffusion of metal atoms and ions may be “promoted” by the presence of pronounced diffusion paths, such as grain boundaries of metal grains, interfaces between the metal and a barrier material, and the like.

For instance, aluminum lines embedded into silicon dioxide and/or silicon nitride are frequently used as metal for metallization layers, wherein, as explained above, advanced integrated circuits having critical dimensions of 0.13 μm or less, may require significantly reduced cross-sectional areas of the metal lines and, thus, increased current densities, which may render aluminum less attractive for the formation of metallization layers due to significant electromigration effects.

Consequently, aluminum is increasingly being replaced by copper that exhibits a significantly lower electric resistivity and exhibits an enhanced resistance to electromigration effects at higher current densities as compared to aluminum. The introduction of copper into the fabrication of microstructures and integrated circuits creates a plurality of severe problems due to copper's characteristic to readily diffuse in silicon dioxide and a plurality of low-k dielectric materials. To provide the necessary adhesion and to avoid the undesired diffusion of copper atoms into sensitive device regions, it is, therefore, usually necessary to provide a barrier layer between the copper and the dielectric material in which the copper lines are embedded. Although silicon nitride is a dielectric material that effectively prevents the diffusion of copper atoms, selecting silicon nitride as an interlayer dielectric material is less then desirable, since silicon nitride exhibits a moderately high permittivity, thereby increasing the parasitic capacitance of neighboring copper lines. Hence, a thin conductive barrier layer that also imparts the required mechanical stability to the copper is formed so as to separate the copper from the surrounding dielectric material and only a thin silicon nitride or silicon carbide or silicon carbonitride layer in the form of a capping layer is frequently used in copper-based metallization layers. Currently, tantalum, titanium, tungsten and their compounds, with nitrogen and silicon and the like, are preferred candidates for a conductive barrier layer, wherein the barrier layer may comprise two or more sub-layers of different composition so as to meet the requirements in terms of diffusion suppressing and adhesion properties.

Another characteristic of copper significantly distinguishing it from aluminum is the fact that copper may not be readily deposited in larger amounts by chemical and physical vapor deposition techniques. In addition, copper may not be efficiently patterned by anisotropic dry etch processes, thereby requiring a process strategy that is commonly referred to as the damascene or inlaid technique. In the damascene process, a dielectric layer is first formed that is then patterned to include trenches and vias which are subsequently filled with copper, wherein, as previously noted, prior to filling in the copper, a conductive barrier layer is formed on sidewalls of the trenches and vias. The deposition of the bulk copper material into the trenches and vias is usually accomplished by wet chemical deposition processes, such as electroplating and electroless plating, thereby requiring the reliable filling of vias with an aspect ratio of 5 and more with a diameter of approximately 0.1 μm or less in combination with trenches having a width ranging from approximately 0.1 μm or less to several μm. Although electrochemical deposition processes for copper are well established in the field of electronic circuit board fabrication, a substantially void-free filling of high aspect ratio vias is an extremely complex and challenging task, wherein the characteristics of the finally obtained copper metal line significantly depend on process parameters, materials and geometry of the structure of interest. Since the geometry of interconnect structures is determined by the design requirements and may, therefore, not be significantly altered for a given microstructure, it is of great importance to estimate and control the impact of manufacturing processes involved in the fabrication of metallization layers and of materials, such as conductive and non-conductive barrier layers, of the copper microstructure and their mutual interaction on the characteristics of the interconnect structure so as to insure both high yield and the required product reliability.

Accordingly, a great deal of effort has been made in investigating the degradation of copper lines, especially in view of electro and stress migration and undue conductivity reduction in highly scaled devices, in order to find new materials and process strategies for forming copper-based metal lines, as increasingly tighter constraints are imposed with respect to the electro and stress migration and conductivity characteristics of copper lines with the continuous shrinkage of feature sizes in advanced devices. Although the exact mechanism of electro and stress migration in copper lines is still not quite fully understood, it turns out that voids positioned in and on sidewalls and interfaces, large bulk voids and residuals at the via bottom may have a significant impact on the electro and stress migration behavior. Empirical research results indicate that the degree of electro and stress migration may frequently depend on the material composition of the metal, the crystalline structure of the metal, the condition of any interfaces to neighboring materials, such as conductive and dielectric barrier layers, and the like.

For instance, in metal lines, grain boundaries may provide preferred diffusion paths for stress and current induced material transport events. Consequently, as the reduction of the width of metal lines tends to generate smaller grains, disproportionally increased electro and stress migration may occur. Irrespective of whether grain boundaries form preferred diffusion paths in copper-based metal lines, the increased number of grain boundaries may nevertheless significantly increase the overall resistivity of the copper-based line owing to increased electron scattering at the grain boundaries, as will be explained in more detail with reference to FIGS. 1a-1c.

FIG. 1a schematically illustrates a top view of a sophisticated semiconductor device 100 comprising a metallization system 150. As previously explained, the metallization systems of complex integrated circuits and the like may require a plurality of individual metallization layers wherein, for convenience, a single metallization layer 110 is illustrated. The metallization layer 110 typically comprises a dielectric material, such as a low-k dielectric material, which is to be understood as a low-k dielectric material having a dielectric constant of 3.0 and less. Moreover, a plurality of metal lines 112 are embedded in the dielectric material 111, wherein, typically, the metal lines 112 may comprise a highly conductive material, such as copper. The metal lines have a specified width 112W which may be selected differently for different metal lines in the same metallization layer, but which may typically represent a critical device dimension for at least a plurality of metal lines, that is, the corresponding width 112W may represent a minimum lateral dimension that may be reproducibly and reliably formed in a corresponding metallization layer based on the associated lithography and patterning techniques. As previously discussed, the increasing packing density in the device level of sophisticated semiconductor devices may not only require an increased number of stacked metallization layers but may also necessitate reduced lateral dimensions of the metal lines 112. Consequently, the current density may be at a moderately high level, for instance several kA per m², which may require appropriately designed interfaces in the metal lines to avoid undue material diffusion during operation of the device.

FIG. 1b schematically illustrates a cross-sectional view as indicated by section 1b of FIG. 1a. As illustrated, the metal line 112 may typically comprise a conductive barrier material 112B that may reliably confine a core metal material 112A that is typically provided in the form of a copper material. Furthermore, in sophisticated applications, the core material 112A may be confined on the basis of a cap layer 112C, which may typically be provided in the form of a conductive cap material, wherein a plurality of specific material compositions, such as an alloy comprised of cobalt, tungsten, phosphorous and the like, may be used in view of enhancing the overall electromigration performance of the metal line 112. That is, it is believed that the provision of the conductive cap layer 112C may provide a “strong” interface with the core material 112A so that replacement of any material at the interface may require a moderately high energy level, thereby enhancing the resistance against electromigration effects. However, the conductivity of the cap material 112C may typically be reduced compared to the conductivity of the copper material 112A, thereby compromising the overall electrical performance of the metal line 112 for a given cross-sectional area of the metal line 112. Furthermore, as is illustrated, the core material 112A may have a certain degree of granularity, i.e., metal grains 112G, typically provided in the metal line, wherein the average grain size may usually vary along the depth of the metal line 112, in particular when a reduced lateral dimension 112W (see FIG. 1a) is to be used to comply with the overall design rules of the device 100.

FIG. 1c schematically illustrates a cross-sectional view along the line 1c of FIG. 1a. Thus, the current flow direction represents the horizontal direction in FIG. 1c. Moreover, as is illustrated, the average grain size of the grains 112G may become significantly smaller towards the bottom of the metal line 112 for critical lateral dimensions of the metal line 112 in the range of approximately 200 nm and less.

Typically, the metallization layer 110 of the device 100 may be formed by well-established process techniques in which the dielectric material 111 may be deposited by any appropriate deposition technique, such as chemical vapor deposition (CVD), plasma enhanced CVD and the like, depending on the material characteristics of the material 111. For example, frequently, an etch stop material 113 may be deposited, for instance in the form of a silicon nitride material, a nitrogen-containing silicon carbide material and the like, followed by the deposition of a low-k material, depending on the overall device requirements. Thereafter, complex patterning regimes using sophisticated lithography and etch techniques are applied so as to form corresponding trenches and via openings (not shown) which are subsequently coated with the conductive barrier material 112B, for instance on the basis of sputter deposition and the like. For example, tantalum and tantalum nitride are well-approved barrier materials for a core material in the form of copper. Next, a seed layer may be deposited, if required, and thereafter the core material 112A may be deposited by an electrochemical deposition technique, followed by the removal of any excess material, for instance by chemical mechanical polishing (CMP). Thereafter, any appropriate post-deposition treatments may be performed, for instance specific anneal processes, in order to increase overall size of the grains 112G, since, in general, an increased grain size is advantageous with respect to a reduced resistivity and also with respect to enhanced electromigration behavior. It turns out, however, that the grain size may significantly drop at the bottom of the metal lines 112, thereby increasing the overall resistivity of the metal line 112 while also enhancing the probability of the occurrence of increased electromigration effects during the operation of the semiconductor device 100. Since the problem of a reduced grain size in the depth of the metal lines may be further pronounced on further scaling of the overall device dimensions, significant performance degradation in view of electrical performance and reduced reliability may result.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides techniques and semiconductor devices in which enhanced performance with respect to electromigration may be accomplished in sophisticated metallization systems by incorporating metal regions at intermediate positions of critical metal lines in order to provide, at least locally, an increased average grain size in the vicinity of the bottom of the adjacent metal line sections. Consequently, the locally provided intermediate metal areas having an increased average grain size at a depth that corresponds to the bottom of corresponding metal line sections connecting to the intermediate metal region may provide a certain “barrier effect” with respect to electromigration induced material diffusion along the metal line. Consequently, corresponding intermediate metal regions may be positioned on the basis of a predetermined “allowable” intermediate section length to provide a corresponding electromigration barrier along the entire length of a corresponding critical metal line. In some illustrative aspects disclosed herein, this may be accomplished by providing the intermediate metal region at least with an increased width compared to the remaining metal line, thereby providing enhanced conditions for creating metal grains of increased size even at a depth that corresponds to the bottom of the metal line sections connecting to the intermediate metal region. Consequently, enhanced electromigration behavior may be accomplished by providing specifically designed metallization layers, however, substantially without contributing to increased overall process complexity, thereby extending the scalability of well-established manufacturing techniques for forming sophisticated metallization systems.

One illustrative method disclosed herein comprises forming a first metal line segment in a dielectric layer of a metallization layer of a semiconductor device, wherein the first metal line segment extends along a length direction and has a first width and a first depth. The method further comprises forming an intermediate metal region connecting to the first metal line segment and having a second width and a second depth, wherein the second width and depth are greater than the first width and depth. Finally, the method comprises forming a second metal line segment connecting to the intermediate metal region, wherein the second metal line segment extends along the length direction and has the first width and the first depth.

A further illustrative method disclosed herein relates to forming a metal line of a metallization system of a semiconductor device. The method comprises determining a target length of the metal line and a maximum allowable intermediate section length for the metal line. Furthermore, the metal line is formed with the target length and with a first width and a first depth. Finally, the method comprises forming an intermediate metal region in the metal line when the maximum allowable intermediate section length is less than the target length, wherein the intermediate metal region has a second width that is greater than the first width.

One illustrative semiconductor device disclosed herein comprises a substrate and a metallization layer comprising a dielectric material. Moreover, the semiconductor device comprises a metal line comprising a first metal line section and a second metal line section formed in the dielectric material, wherein the first and second metal line sections have a first width and a first depth. The first and second metal line sections comprise first metal grains having a first average grain size at the first depth. Additionally, the semiconductor device comprises an intermediate metal region formed between the first metal line section and the second metal line section, wherein the intermediate metal region comprises second metal grains of a second average grain size at the first depth and wherein the first average grain size is less than the second average grain size.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a conventional semiconductor device including a metallization layer with metal lines of reduced width;

FIGS. 1b-1c schematically illustrate respective cross-sectional views of the device of FIG. 1a, thereby illustrating critical metal lines having a different average grain size at the top of the metal line and the bottom thereof due to conventional manufacturing techniques;

FIG. 2a schematically illustrates a top view of a portion of a metallization layer in which an appropriate allowable intermediate section length may be determined in order to appropriately position corresponding intermediate metal regions for providing a barrier with respect to increased electromigration, according to illustrative embodiments;

FIGS. 2b-2c schematically illustrate a cross-sectional view and a top view, respectively, of the semiconductor device of FIG. 2a during a specific manufacturing stage in forming the metal lines and corresponding intermediate metal regions, according to illustrative embodiments;

FIGS. 2d-2e schematically illustrate a cross-sectional view and a top view, respectively, of the semiconductor device of FIGS. 2b-2c in a further advanced manufacturing stage, according to illustrative embodiments;

FIGS. 2f-2h schematically illustrate cross-sectional views of the metallization system according to further illustrative embodiments in which one or more of the intermediate metal regions may terminate in a dielectric material without connecting to a further metal region; and

FIGS. 2i, 2j and 2k schematically illustrate cross-sectional views and a top view, respectively, during an intermediate manufacturing stage in forming metal lines having an intermediate metal region, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to techniques and semiconductor devices in which superior performance with respect to electromigration of metal lines may be accomplished by incorporating metal regions or features that provide an increased average grain size along the entire depth of corresponding metal lines connecting to the corresponding metal lines or features. In some illustrative embodiments, these intermediate metal regions represent metal line extensions in order to locally increase the line width after a defined length of the metal line. That is, a corresponding maximum allowable intermediate section length for a given metal line may be determined which may thus represent the maximum distance between two subsequent intermediate metal regions for a given metal line. Consequently, the layout of a corresponding metallization layer may be appropriately modified to incorporate the corresponding intermediate metal regions, which may provide an increased metal volume so that the average grain size obtained at a depth corresponding to the bottom of the remaining metal line sections is increased. Consequently, upon establishing a current flow in the metal line, the increased grain size at the intermediate metal region may provide a barrier that significantly reduces the electromigration induced material diffusion. For example, the maximum allowable intermediate section length may be selected such that a significant degree of electromigration may be suppressed during standard operational conditions, thereby significantly reducing the overall electromigration of the entire metal line. In some illustrative embodiments, the intermediate metal regions may be incorporated into the metal lines without requiring additional process steps, thereby providing a high degree of compatibility with conventional manufacturing techniques while nevertheless ensuring enhanced electromigration behavior and thus scalability of these manufacturing techniques. For example, in some illustrative embodiments, the intermediate metal regions may additionally provide the electrical connection to a lower lying metallization layer, thereby also enhancing the overall electrical performance of a corresponding via structure due to the increased cross-sectional area of the corresponding “vias.” In other cases, in addition to or alternatively to the corresponding increased vias, the intermediate metal regions may be incorporated at specific locations in the metal lines so as to terminate in a dielectric material, thereby not connecting to any further metal regions. In this case, a superior flexibility in designing the overall layout of the metallization layer may be provided, since an appropriate maximum allowable intermediate section length may be defined without requiring the presence of a corresponding required electrical connection to a lower lying metallization layer.

It should be appreciated that the present disclosure is highly advantageous in the context of copper-based metallization systems provided for semiconductor devices having a high packing density in the device level, for instance by using critical dimensions of transistor elements of approximately 50 nm and less, since, in this case, a high density of metal lines is to be provided in the corresponding metallization layers, thereby requiring reduced lateral dimensions of the metal lines. In other cases, the principles disclosed herein may also be applied to metallization systems formed on the basis of other metal materials, such as aluminum and the like, in which the reduced lateral dimensions of the metal lines may result in a reduction of grain size along the depth direction of the metal lines. Thus, the present disclosure should not be considered as being restricted to any specific metal materials unless such restrictions are specifically set forth in various embodiments described in the specification or in the appended claims.

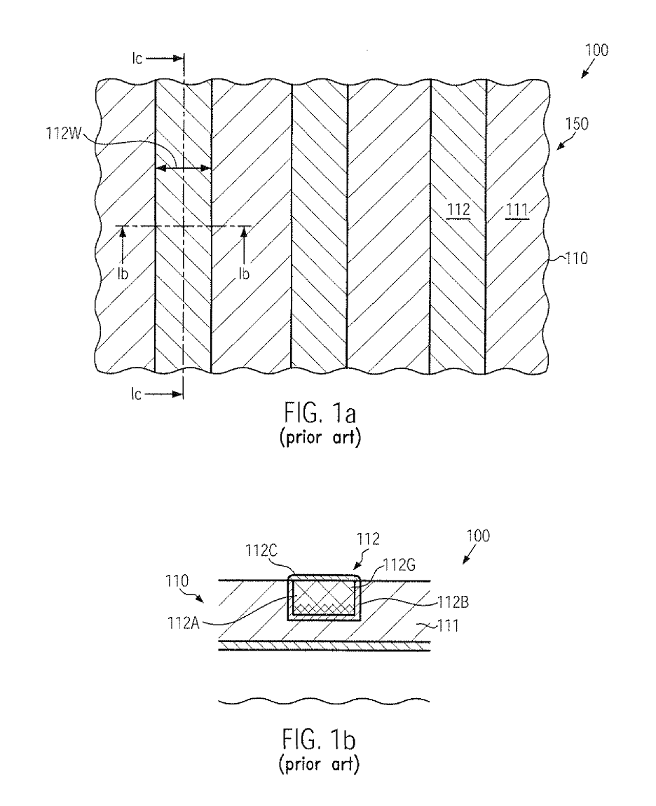

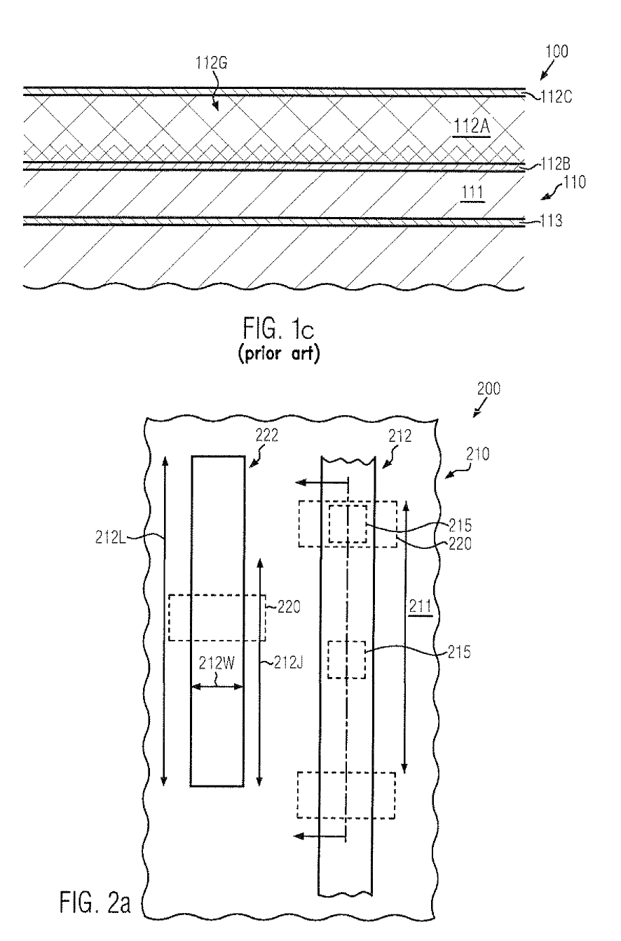

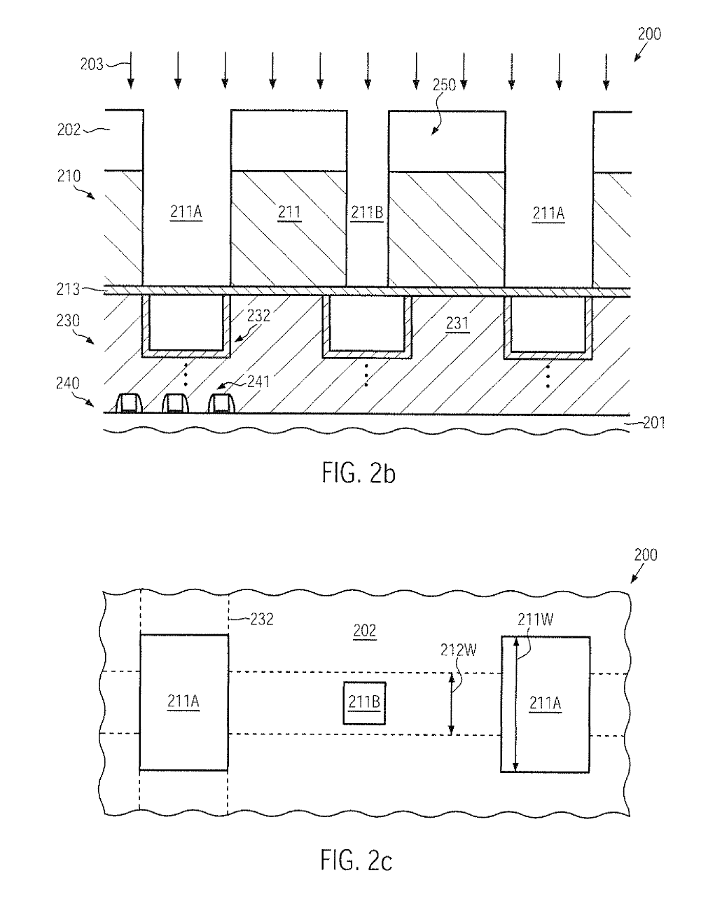

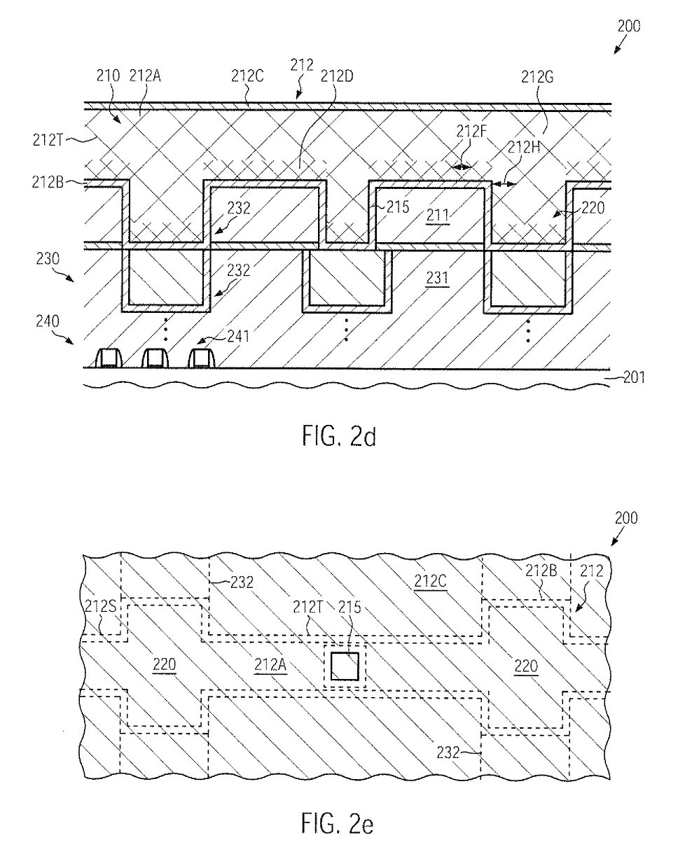

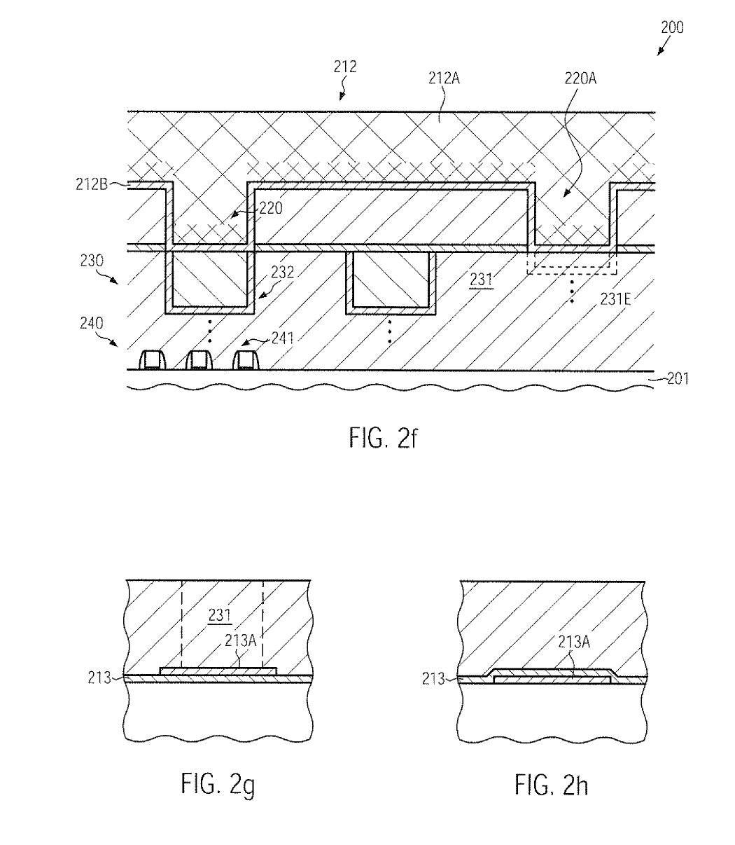

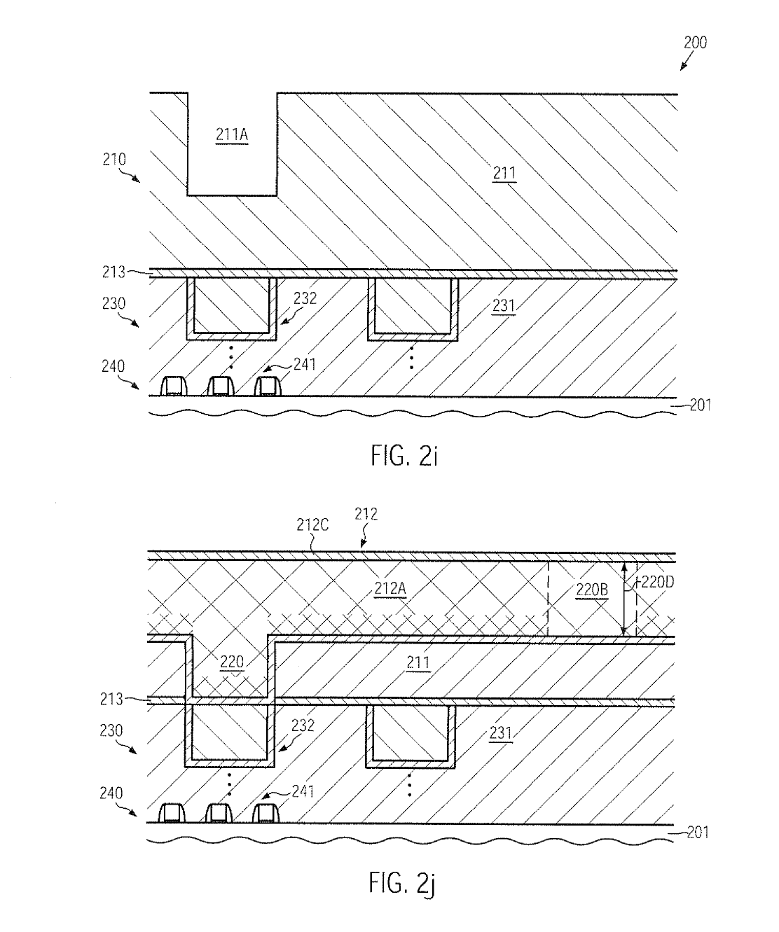

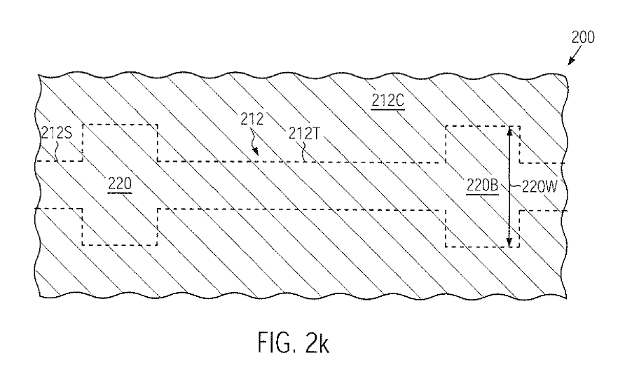

With reference to FIGS. 2a-2j, further illustrative embodiments will now be described in more detail, wherein reference may also be made to FIGS. 1a-1c, if appropriate.

FIG. 2a schematically illustrates a top view of a semiconductor device 200 comprising a metallization system of which a single metallization layer 210 is illustrated in FIG. 2a. The metallization layer 210 may comprise an appropriate dielectric material 211, which may contain any appropriate material composition, such as a low-k dielectric material and the like, as is also previously explained with reference to the semiconductor device 100. Furthermore, the metallization layer 210 may comprise a plurality of metal lines 212, 222 having a width 212W, which, in sophisticated applications, may represent a critical lateral dimension and may be approximately 200 nm and less, such as 100 nm and less, if highly advanced metallization systems are considered. Moreover, the metal lines 212, 222 may have a length 212L, which, however, may be different for the various metal lines in the metallization layer 210. For example, the length 212L may represent a target length of the metallization line 222, while the metal line 212 may have a significantly greater length depending on the overall layout of the metallization layer 210. As previously explained, the specific width dimensions of sophisticated metal lines may result in a corresponding deteriorated average grain size, in particular at the bottom of the corresponding metal lines, which may result in significant electromigration. Consequently, in some illustrative embodiments, a maximum allowable intermediate section length, indicated a 212J, may be defined for metal lines of a given width in order to appropriately incorporate an “electromigration barrier” so that a distance from one electromigration barrier to a neighboring electromigration barrier corresponds to the section length 212J or less. In this manner, a desired degree of suppression of electromigration effects may be accomplished for a given overall configuration of the metal lines under consideration. In the example illustrated in FIG. 2a, it may be assumed that the width 212W represents a minimum width used in the metallization layer 210 and thus may be considered as a critical dimension, which may result in a reduced depth profile of the average grain size, as previously explained. Thus, the length 212J may be appropriately selected for the width 212W and in view of the corresponding manufacturing techniques used for forming the metal lines 212 and 222, since, typically, the corresponding manufacturing techniques, as well as materials used, such as barrier materials and the like, may also have a significant influence on the finally obtained grain structure in the metal lines 222 and 212. For instance, a desired maximum allowable intersection length 212J may be appropriately selected by performing respective test runs and evaluating the electromigration behavior of the corresponding metal lines, wherein corresponding intermediate metal regions may also be positioned at various distances in order to obtain a desired electromigration behavior.

For example, the metal line 222 may have a target length 212L that is greater than the corresponding predetermined intersection length 212J, thereby requiring at least one intermediate metal region 220 in order to provide the required superior electromigration behavior. Similarly, the metal line 212, having an increased length, may be appropriately designed so as to receive corresponding intermediate metal regions 220 that are spaced apart from each other by at most the length 212J. For example, the intermediate metal regions 220 may be positioned so as to concurrently act as a via 215 in order to establish an electrical connection to a lower lying metallization layer. Depending on the overall design constraints of the metallization layer 210 and the lower lying metallization layer, a corresponding metal region 220 may not be desirable at a via 215, which may have corresponding reduced lateral dimensions in accordance with conventional design strategies. Consequently, on the principles discussed above, an appropriate layout for the metallization layers of the device 200 may be established so as to maintain an intermediate section length of critical metal lines below the corresponding length 212J.

FIG. 2b schematically illustrates the device 200 in an intermediate manufacturing stage in forming the metallization layer 210 of a metallization system 250 of the device 200. As illustrated, the semiconductor device 200 may comprise a device level 240 formed above a substrate 201. For example, the substrate 201 may represent any appropriate carrier material for forming thereon and thereabove the device layer 240 in the form of a semiconductor material, such as a silicon material and the like. For example, the substrate 201 may represent a semiconductor material, such as a silicon material, wherein, also, at least locally across the substrate 201, an insulating material may be provided. In this case, an SOI (semiconductor-on-insulator) configuration may be provided. The device level 240 may comprise any appropriate semiconductor material and circuit elements 241 formed in and above the semiconductor material in accordance with the overall circuit layout of the device 200. For example, as previously discussed, the circuit elements 241 may be formed on the basis of critical dimensions of approximately 50 nm and less, if sophisticated semiconductor devices are considered. For example, a critical dimension in this sense may be a gate length of planar field effect transistors, a width of fins of three-dimensional multiple gate transistors and the like. The device level 240 may be connected to the metallization system 250 on the basis of an appropriate contact structure (not shown). Furthermore, a further metallization layer 230 may be formed below the metallization layer 210 and may comprise an appropriate dielectric material 231, in which may be formed respective metal regions or lines 232 having an appropriate overall configuration. It should be appreciated that the metallization layer 230 may have basically a configuration as will also be described with reference to the metallization layer 210 so that a detailed description of the metallization layer 230 may be omitted. That is, the metal lines 232 may be formed on the basis of similar concepts as will be described with reference to the metal lines of the layer 210 in order to enhance the overall electromigration performance, as previously explained.

In the manufacturing stage shown, the dielectric material 211 may comprise openings 211A, 211B with lateral dimensions which may substantially correspond to the lateral dimensions of the metal regions 220 and the via 215, as illustrated in FIG. 2a. For this purpose, an appropriate etch mask 202 may be formed above the dielectric material 211 in accordance with well-established lithography techniques, wherein, however, an appropriate lithography mask may be used so as to appropriately define the lateral dimensions of the openings 211A.

FIG. 2c schematically illustrates a top view of the device 200 according to the manufacturing stage of FIG. 2b. Thus, as illustrated, the mask material 202 may include the openings 211A, 211B, wherein the openings 211A may have a width 211W that is greater than the width 212W of a metal line section still to be formed in the dielectric material 211 (FIG. 2b). Consequently, during the subsequent manufacturing process, the openings 211A may provide a significantly increased copper volume so as to enable the creation of metal grains having an increased average size at a depth level that may correspond to the bottom of the metal line sections still to be formed.

The semiconductor device 200 as shown in FIGS. 2b-2c may be formed on the basis of the following processes. After fabricating the circuit elements 241 in the device level 240 on the basis of well-established manufacturing techniques, a corresponding contact structure may be formed followed by appropriate manufacturing sequences for providing a plurality of metallization layers of the metallization system 250. In each of the metallization layers, similar process techniques may be used, as will also be described with reference to the metallization layer 210. Hence, a detailed description of the formation of these metallization layers, including the metallization layer 230, may be omitted. Thereafter, the dielectric material 211 may be deposited, for instance by any appropriate deposition technique, such as CVD, spin-on techniques and the like. Thereafter, the etch mask 202 may be formed, for instance, by providing a resist material, a hard mask material, if required, in combination with anti-reflective coating (ARC) materials and the like. Based on corresponding lithography processes using an appropriately designed lithography mask to define the position and lateral size of the openings 211A, the etch process 203 may be performed so as to transfer the mask pattern into the dielectric material 211, wherein the etch process may be controlled on the basis of an etch stop material 213. Consequently, the openings 211A may be concurrently formed with other via openings, such as the opening 211B, without requiring any additional process steps.

FIG. 2d schematically illustrates the semiconductor device 200 in a further advanced manufacturing stage. As illustrated, the metal line 212 is formed in the dielectric material 211 and has incorporated therein the intermediate metal regions 220 and a corresponding via 215. As illustrated, the metal line 212 may comprise a conductive barrier material 212B and a core material 212A, such as a copper material. Furthermore, a cap layer 212C may provide confinement of the core material 212A at a top surface thereof. In one illustrative embodiment, the cap layer 212C may be provided in the form of an appropriate dielectric material, which may additionally act as an etch stop material for forming thereabove a further metallization layer. Hence, for given dimensions of the metal line 212, enhanced conductivity may be accomplished since more of the core material 212A may be provided in the metal line 212 rather than requiring a conductive cap material. It should be appreciated, however, that the cap layer 212C may also be provided as a conductive cap material, if desired. The core material 212A of the metal line 211 may include corresponding metal grains 212T, the average size of which may become significantly smaller at the bottom 212D of the metal line 212, as previously explained. For example, an average grain size 212F at the bottom 212D may be several tenths of nanometers compared to a grain size of several hundred nanometers and more in upper areas of the metal line 212. Due to the increased lateral dimensions of the intermediate metal regions 220, an average grain size 212H at a depth level that substantially corresponds to the bottom 212D of the remaining portions of the metal line 212 may be significantly greater and may be comparable to the grain size at the upper part of the metal line 212. For example, the average grain size 212H may be at least 100 nm and more. Consequently, the intermediate metal regions 220 may act as efficient electromigration barriers when a current flow is established in the metal line 212.

Typically, the metal line 212 of the semiconductor device 200 may be formed on the basis of well-established process techniques including an appropriate patterning sequence for forming a corresponding trench in the dielectric material 211, followed by the deposition of the conductive barrier material 212B. Thereafter, the core material 212A may be deposited, for instance, by electroplating, electroless plating and the like, wherein, if required, a seed layer may be deposited prior to the deposition of the actual core material 212A. Thereafter, any excess material may be removed and the cap layer 212C may be deposited, for instance, by CVD and the like. For example, well-established etch stop and dielectric barrier materials may be provided, for instance in the form of nitrogen-containing silicon carbide and the like. In other cases, a conductive cap material may be provided by electroless plating and the like.

FIG. 2e schematically illustrates a top view of the semiconductor device 200 in a manufacturing stage corresponding to FIG. 2d. For convenience, the metal line 212, i.e., the core material 212A and the conductive barrier material 212B, may be illustrated in dashed lines, although these materials may be covered by the cap layer 212C. Thus, the metal line 212 may comprise a first line segment 212S connecting to the intermediate metal region 220 providing the electromigration barrier effect and also electrically connecting to the lower lying metal line 232, also indicated by dashed lines. Moreover, a further metal line segment 212T may connect to the region 220 and may also connect to the subsequent intermediate metal region 220 at the right side of the via 215. Similarly, this intermediate metal region 220 may also connect to a lower lying metal line 232. Consequently, by appropriately designing the overall layout of the metallization layer 210, possibly in combination with layer 230 (FIG. 2c), corresponding electromigration barriers may be positioned with a desired maximum section length while at the same time providing the required electrical connection to the lower lying metallization lines 232. Thus, by providing the intermediate metal regions 220 with an increased width and depth compared to the metal line sections 212S, 212T, a superior grain structure may be accomplished while also providing electrical connection to the lower lying metallization layer.

FIG. 2f schematically illustrates a cross-sectional view of the device 200 in which one or more of the electromigration barriers may be provided in the form of a “dummy metal region” which may not connect to a metal region of a lower lying metallization level. For example, as illustrated in FIG. 2f, an intermediate metal region 220A may terminate in the dielectric material 231 of the metallization layer 230. Consequently, an efficient electromigration barrier may be provided at positions at which electrical connection to a metal line of the layer 230 may not be required. It should be appreciated that a certain degree of material erosion of the dielectric material 231 during the corresponding patterning sequence, as indicated by 231E, may substantially not negatively affect the further processing of the device since the corresponding conductive barrier material 212B may reliably provide confinement of the core material 212A at the bottom of the intermediate metal region 220A. Consequently, the dummy region 220A may be provided with any desired lateral dimensions and with an increased depth compared to the metal line sections 212S, 212T, thereby providing a superior grain structure, as previously explained.

FIG. 2g schematically illustrates the device 200 according to further illustrative embodiments in which an enhanced etch resistivity may be accomplished in the vicinity of the region 220A (FIG. 2f). For this purpose, an additional etch stop layer 213A may be locally provided in order to enhance etch resistivity since, generally, the dielectric material 231 may have a different etch behavior compared to the metal lines 232 of the layer 230 (see FIG. 2f). Thus, during a corresponding patterning sequence for forming via openings to the lower lying metal lines, enhanced integrity of the dielectric material 231 in the vicinity of the intermediate metal region 220A may be accomplished. For this purpose, the additional etch stop material 213A may be deposited after forming the regular etch stop material 213 and performing a corresponding patterning process.

FIG. 2h schematically illustrates a similar configuration in which the additional etch stop material 213A may be formed first and patterned so as to be spatially restricted to the neighborhood of the dummy region 220A, and thereafter the regular etch stop material 213 may be deposited in accordance with well-established process strategies.

With reference to FIGS. 2i-2k, further illustrative embodiments will now be described in which at least some of the intermediate metal regions may not extend down to the lower lying metallization layer.

FIG. 2i schematically illustrates a cross-sectional view of the device 200 in a manufacturing stage in which an opening 211A is formed in an upper portion of the dielectric material 211 of the metallization layer 210. As previously explained, the opening 211A may have lateral dimensions so as to act as an electromigration barrier while also connecting to one of the metallization lines 232 of the metallization layer 230. During the further processing, an appropriate etch mask may be provided so as to define the position and the lateral size of a corresponding metal line, wherein an intermediate metal region of increased width is also to be formed with an appropriate distance to the opening 211A in order to provide the desired electromigration reducing effect, as previously explained. Thus, during the corresponding patterning process, a trench may be formed in the upper portion of the material 211, while the depth of the opening 211A may be further increased so as to finally connect to the metal line 232. It should be appreciated, however, that other patterning regimes may also be used in which the opening 211A may be formed so as to extend down to at least the etch stop layer 213 and thereafter the corresponding trench for the metal line may be formed, as is, for instance, explained above with reference to FIG. 2b. After forming the corresponding trench including a portion of increased width, further processing may be continued by depositing a conductive barrier material and filling the openings with the desired core material, as is also previously described.

FIG. 2j schematically illustrates the semiconductor device 200 in a further advanced manufacturing stage. As illustrated, the metal line 212 is formed in the dielectric material 211, wherein the intermediate metal region 220 connects to the metal line 232, while also a further intermediate metal region 220B with increased width provides the desired electromigration reducing effect. That is, the average grain size in the intermediate region 220B may be increased along the entire depth 220D due to the increased lateral width of the region 220B.

FIG. 2k schematically illustrates a top view of the device 200 according to FIG. 2j. As illustrated, the increased lateral width 220W compared to the lateral width of the remaining metal line sections, such as the sections 212S, 212T, may also provide superior conditions during the deposition of a core material 212A and the subsequent treatment thereof so that an increased average grain size may be obtained along the entire depth, as described above with reference to FIG. 2j. Consequently, a corresponding electromigration barrier effect may also be obtained in device areas in which an increased depth of a corresponding intermediate metal region, such as the region 220B, may not be desirable, for instance, in view of the overall design of the lower lying metallization layer 230 and the like.

As a result, the present disclosure provides semiconductor devices and manufacturing techniques in which an intermediate metal region, which may also be referred to as “grain size enlargement” area, may be formed in metal lines after a well-defined section length thereof, in order to provide a superior grain structure at a height level that corresponds to the bottom of the metal line. This may be accomplished by providing at least an increased lateral width for the intermediate metal regions, which may result in superior conditions during the deposition and the subsequent treatment of a highly conductive material, such as copper. In some illustrative embodiments, the intermediate metal region of increased lateral size may also be used as a via connecting to a lower lying metal region, thereby also providing enhanced electrical performance. In other cases, corresponding “dummy” metal regions may be provided which may terminate in a dielectric material, thereby also providing an increased depth and lateral dimension in order to obtain a superior grain structure at a height level corresponding to the bottom of the remaining metal lines. In still other illustrative embodiments, at least an increased lateral width may be established at specific portions of a metal line in order to provide the electromigration barrier effect. Consequently, enhanced electromigration behavior may be accomplished without adding to the overall process complexity.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first metal line segment in a dielectric layer of a metallization layer of a semiconductor device, said first metal line segment extending along a length direction and having a first width and a first depth;
forming an intermediate metal region connecting to said first metal line segment and having a second width and a second depth, said second width and said second depth being greater than said first width and said first depth; and
forming a second metal line segment connecting to said intermediate metal region, said second metal line segment extending along said length direction and having said first width and said first depth.

2. The method of claim 1, wherein forming said first and second metal line segments and said intermediate metal region comprises forming first and second trenches with said first depth and forming an opening having said second depth in a dielectric material of said metallization layer and filling in a metal in said first and second trenches and said opening by performing a common deposition process.

3. The method of claim 2, further comprising forming a conductive barrier layer on exposed surface areas of said first and second trenches and said opening prior to performing said common deposition process.

4. The method of claim 2, wherein said opening is formed so as to extend to a metal region of a second metallization layer positioned below said metallization layer.

5. The method of claim 1, wherein said intermediate metal region is formed so as to terminate in a dielectric material of a second metallization layer positioned below said metallization layer.

6. The method of claim 5, further comprising forming an additional etch stop material in said dielectric material of said second metallization layer, wherein said additional etch stop material is spatially restricted to an area substantially corresponding to said intermediate metal region.

7. The method of claim 1, further comprising forming a cap layer on said first and second metal line segments and said intermediate metal region.

8. The method of claim 7, wherein said cap layer is comprised of a dielectric material.

9. The method of claim 1, wherein said first width is approximately 200 nm or less.

10. The method of claim 1, wherein said first and second metal line segments and said intermediate metal region comprise copper.

11. A method of forming a metal line of a metallization system of a semiconductor device, the method comprising:
determining a target length of said metal line and a maximum allowable intermediate section length for said metal line;
forming said metal line with said target length and with a first width and a first depth; and
forming an intermediate metal region in said metal line when said maximum allowable intermediate section length is less than said target length, said intermediate metal region having a second width greater than said first width.

12. The method of claim 11, wherein said intermediate metal region is formed so as to have a second depth that is greater than said first depth.

13. The method of claim 11, wherein forming said intermediate metal region comprises forming said intermediate metal region so as to extend to a metal region of a metallization layer that is positioned below said metal line.

14. The method of claim 11, wherein forming said intermediate metal region comprises forming said intermediate metal region so as to terminate in a dielectric material.

15. The method of claim 11, wherein said metal line and said intermediate metal region are formed by performing at least a common metal deposition process for said metal line and said intermediate metal region.

16. The method of claim 11, wherein said intermediate metal region is formed together with a via connecting said metal line with a metal region of a metallization layer positioned below said metal line.

17. A semiconductor device, comprising:
a substrate;
a metallization layer comprising a dielectric material;
a metal line comprising a first metal line section and a second metal line section formed in said dielectric material, said first and second metal line sections having a first width and a first depth, said first and second metal line sections comprising first metal grains of a first average grain size at said first depth; and
an intermediate metal region formed between said first metal line section and said second metal line section, said intermediate metal region comprising second metal grains of a second average grain size at said first depth, said first average grain size being less than said second average grain size.

18. The semiconductor device of claim 17, wherein said intermediate metal region has a second width that is greater than said first width.

19. The semiconductor device of claim 18, wherein said intermediate metal region has a second depth that is greater than said first depth.

20. The semiconductor device of claim 17, wherein said intermediate metal region connects to a metal region of a second metallization layer formed below said metallization layer.

21. The semiconductor device of claim 17, wherein said intermediate metal region terminates in a dielectric material, at least in a depth direction.

22. The semiconductor device of claim 17, wherein said intermediate metal region comprises a continuous conductive barrier material formed on sidewalls of said intermediate metal region.

23. The semiconductor device of claim 17, wherein said metal line comprises a core metal material and wherein a cap layer is formed on said core metal material.

24. The semiconductor device of claim 23, wherein said cap layer is comprised of a dielectric material.

25. The semiconductor device of claim 17, further comprising a device level comprising transistor elements having critical dimensions of approximately 50 nm or less.
